(19) United States
(12) Patent Application Publication
(10) Pub. No.: US 2009/0168361 A1
(43) Pub. Date: Jul. 2, 2009

(54) PRINTED CIRCUIT BOARD ASSEMBLY

(75) Inventors: CHIH-HANG CHAO, Tu-Cheng (TW); YU-HSU LIN, San Jose, CA (US); JENG-DA WU, Tu-Cheng (TW); LEI GUO, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/180,221

(22) Filed: Jul. 25, 2008

(30) Foreign Application Priority Data
Dec. 29, 2007 (CN) 200720201815.1

(51) Int. Cl. H05K 7/20

(52) U.S. Cl. 361/711; 361/717; 361/719

(57) ABSTRACT

A printed circuit board assembly includes a printed circuit board with a heat generating component attached thereon, a base, and a thermal plate. The heat generating component comprises a side surface. The base defines a receiving room and an opening configured for access into the receiving room. The printed circuit board is received in the receiving room via the opening. The thermal plate is mounted on the base to cover the opening. A conducting piece is formed on the thermal plate and extends into the receiving room. The conducting piece includes a contacting portion extending from the thermal plate and in contact with the side surface. The conducting piece is configured for conducting heat from the heat generating component to the thermal plate. A heat dissipating hole is defined on the thermal plate in alignment with the contacting portion configured for dissipating heat from the base.

### BACKGROUND

1. Technical Field

The present invention relates to a printed circuit board (PCB) assembly having good heat dissipating capability.

2. Description of Related Art

A PCB typically has one or more heat-generating electronic components fixed on a surface of the PCB and installed in a cramped location inside an electronic device enclosure. Often, there is not enough space to install a conventional bulky heat sink onto any electronic component because the PCB is installed in a cramped location. Instead, a thermal plate can be attached onto a surface of the electronic component. The low profile of the thermal plate allows it to be accommodated in the limited space inside the enclosure.

For example, U.S. Pat. No. 6,603,665 discloses a heat dissipating assembly using thermal plates for electronic components mounted on a circuit board. The heat dissipating assembly includes a first thermal plate, a second thermal plate, and an adjusting screw. The first thermal plate forms a plurality of offset portions thereby defining a plurality of recesses at the offset portions. The depths of the recesses correspond to heights of the electronic components. The first and second thermal plates are secured to opposite sides of the circuit board. The first and second thermal plates respectively define first and third holes movably receiving the adjusting screw. The adjusting screw is tightened to improve thermal contact between the offset portions and the electronic components. However, heat in the cover cannot dissipate from the circuit board directly because the offset portions are closed.

Therefore, a new PCB assembly having good heat dissipating capability is desired to overcome the above-described shortcoming.

### BRIEF DESCRIPTION OF THE DRAWINGS

FIG. 1 is an exploded, isometric view of an embodiment of a printed circuit board assembly, the printed circuit board assembly comprising a printed circuit board, a base, and a thermal plate;

FIG. 2 is an isometric view of the thermal plate of the printed circuit board assembly of FIG. 1;

FIG. 3 is an assembled, isometric view of the printed circuit board assembly of FIG. 1; and

FIG. 4 is an isometric view of the printed circuit board assembly of FIG. 1, with the base omitted.

### DETAILED DESCRIPTION OF THE EMBODIMENTS

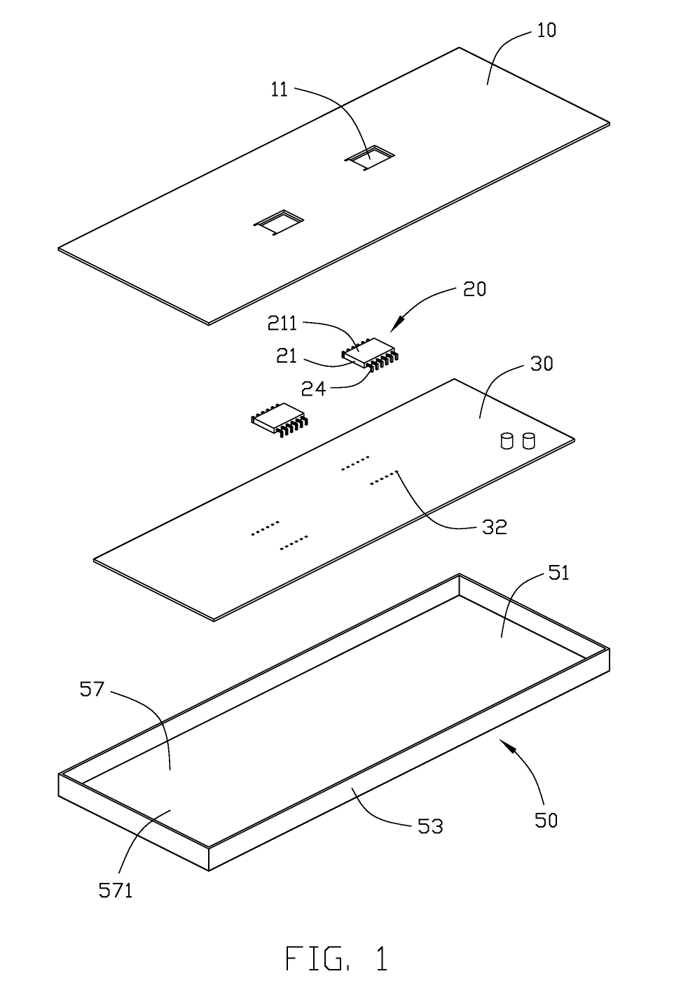

Referring to FIG. 1 a printed circuit board assembly comprises a printed circuit board (PCB) 30, a base 50, and a thermal plate 10. The base 50 and the thermal plate 10 cooperatively receive the PCB 30 and dissipate heat from heat-generating electronic components such as chipsets 20 mounted on the PCB 30, for example, as in the illustrated embodiment. Each chipset 20 includes a main body 21 with a flat side surface 211, and a plurality of signal pins 24 formed on opposite sides of the main body 21 configured for attaching the chipsets 20 onto the PCB 30. The PCB 30 defines a plurality of signal holes 32 corresponding to the signal pins 24.

The base 50 includes a bottom plate 51. A plurality of side plates 53 extend perpendicularly from edges of the bottom plate 51. The bottom plate 51 and the side plates 53 cooperatively define a receiving room 57 configured to receive the PCB 30. The receiving room 57 defines an opening 571 configured for access into the receiving room 57.

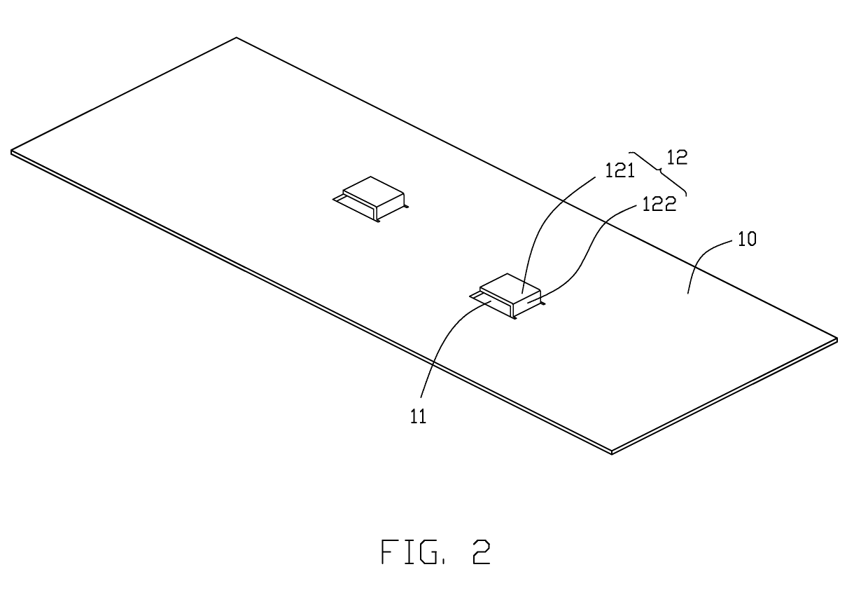

Referring also to FIG. 2, the thermal plate 10 is a flat plate. A plurality of flexible conducting pieces 12 may be formed by punch-outs in the thermal plate 10, thereby defining a plurality of heat dissipation holes 11 corresponding to the chipsets 20. Each conducting piece 12 includes an upright connecting portion 122 connected to an edge of the corresponding heat dissipation hole 11, and a contacting portion 121 extending perpendicularly from an edge of the connecting portion 122. An area of the contacting portion 121 is equal to an area of the side surface 211. The contacting portion 121 is configured to thermally communicate with the chipset 20.

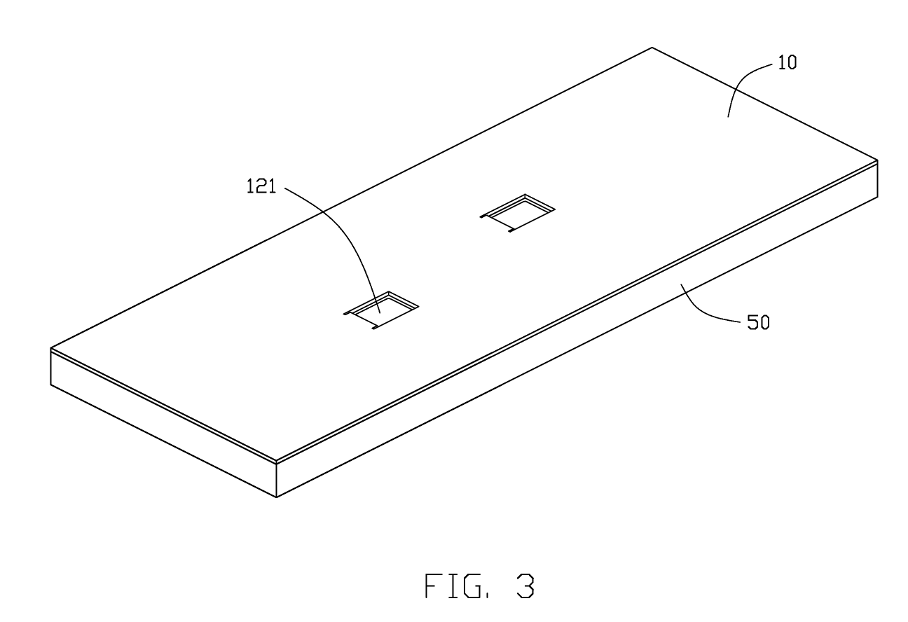

Referring also to FIG. 3, the signal pins 24 are inserted into the signal holes 32, and may be welded to the PCB 30. The PCB 30 is received in the receiving room 57 with the side surfaces 211 facing the opening 571. The thermal plate 10 is positioned over the base 50 and the PCB 30, and secured to the base 50 by a fastening means, for example, welding and riveting.

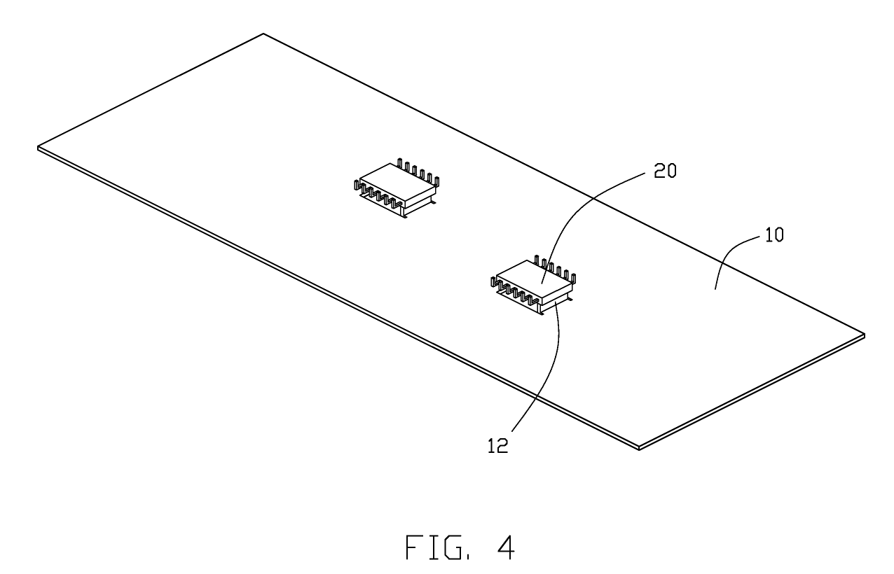

Referring also to FIG. 4, the contacting portions 121 are slightly bent to firmly contact the side surfaces 211, so that heat generated by the chipsets 20 is conducted to the thermal plate 10 via the conducting pieces 12. The heat conducted to the thermal plate 10 is easily dissipated because the thermal plate 10 has a large surface area exposed to the ambient environment. In addition, the heat dissipating holes 11 allow other heat in the base 50 and PCB 30 to dissipate through natural convection.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board assembly, comprising:
a printed circuit board comprising a heat generating component attached on a surface of the printed circuit board, the heat generating component having a side surface;
a base defining a receiving room and an opening configured for access into the receiving room, wherein the printed circuit board is received in the receiving room via the opening with the side surface facing the opening;
a thermal plate mounted to the base to cover the opening, wherein a conducting piece is formed on the thermal plate and extending into the receiving room, the conducting piece is configured for conducting heat from the heat generating component to the thermal plate, the conducting piece comprising a contacting portion in thermal communication with the thermal plate and thermally contacted to the side surface; a heat dissipating hole defined in the thermal plate configured for dissipating heat from the base.

2. The printed circuit board assembly of claim 1, wherein the conducting piece further comprises a connecting portion connected to an edge of the air dissipating hole; the contacting portion extends perpendicularly from an edge of the connecting portion.

3. The printed circuit board assembly of claim 2, wherein the conducing piece and the air dissipation hole are formed by a punch-out in the thermal plate.

4. The printed circuit board assembly of claim 1, wherein the conducting piece is flexible so that the contacting portion may elastically bend to firmly contact the side surface of the chipset.

5. The printed circuit board assembly of claim 4, wherein an area of the contacting portion is equal to an area of the side surface.

6. A printed circuit board assembly, comprising:
a base defining a receiving room with a printed circuit board received therein, the printed circuit board having a heat generating component attached on a surface of the printed circuit board;
a thermal plate mounted to the base, the thermal plate defining a heat dissipating hole in alignment with the heat generating component; a conducting piece is connected to an edge of the air dissipation hole, and extends into the base and in contact with the heat generating component to conduct heat from the heat generating component to the thermal plate.

7. The printed circuit board assembly of claim 6, wherein the receiving room has an opening configured for access into the receiving room; the heat generating component has a side surface that faces the opening.

8. The printed circuit board assembly of claim 7, wherein the conducting piece comprises a connecting portion connected to the edge of the heat dissipation hole, and a contacting portion perpendicularly extending from an edge of the connecting portion; the contacting portion is contacting the side surface of the heat generating component.

9. The printed circuit board assembly of claim 8, wherein an area of the contacting portion of the conducing piece is equal to an area of the side surface of the heat generating component.

10. The printed circuit board assembly of claim 6, wherein the conducing piece and the air dissipation hole are formed by a punch-out in the thermal plate.

11. The printed circuit board assembly of claim 6, wherein the conducting piece is flexible.
